(19) United States
(12) Patent Application Publication
(10) Pub. No.: US 2012/0042935 A1
(43) Pub. Date: Feb. 23, 2012

(54) PHOTOVOLTAIC MODULE WITH COMPOSITE MATERIALS

(75) Inventors: Szu-Han LI, Taoyuan County (TW); Yi-Ling Chen, Taichung City (TW); Ching-Yee Chak, Hong Kong (HK); Wing-Yan Lai, Hong Kong (HK); Hung-Ming Tseng, Taipei City (TW)

(73) Assignee: Du Pont Apollo Limited, Hong Kong (HK)

(21) Appl. No.: 13/195,025

(22) Filed: Aug. 1, 2011

Related U.S. Application Data
(60) Provisional application No. 61/374,260, filed on Aug. 17, 2010.

(51) Int. Cl. H01L 31/048

(52) U.S. Cl. 136/251

(57) ABSTRACT

A photovoltaic module includes a photovoltaic panel and a frame securing to an edge of the photovoltaic panel. The frame includes a metal portion and a composite material of a plastic material and glass fibers or of a silicone resin and glass fibers. The composite material is integrated with the metal portion to form a unitary frame.

### RELATED APPLICATIONS

This application claims priority to U.S. Provisional Application Ser. No. 61,374/260, filed Aug. 17, 2010, which is herein incorporated by reference.

### BACKGROUND

1. Field of Invention

The present invention relates to a photovoltaic module. More particularly, the present invention relates to a photovoltaic module with light-weighted frame.

2. Description of Related Art

In recent years, awareness of ecological problems has been raised worldwide. Among other things, the global warming resulting from CO₂ emission is a serious concern, and clean energy has been increasingly desired. In such a circumstance, a solar cell shows great promise to serve as a source of clean energy in terms of its safety and operability.

The solar cell includes a photoelectric conversion layer for converting light into electricity, typical materials of which include single-crystal silicon semiconductor, polycrystalline silicon semiconductor, amorphous silicon-based semiconductor, groups III-V compound semiconductor, groups II-VI compound semiconductor and groups I-III-VI2 compound semiconductor.

When using solar cell modules, durability with respect to the external environment, including temperature, humidity, and impact, is required. Therefore, ordinary solar cell modules are constructed such that: solar cells are sealed with a filler; a weather-resistant film or glass is provided as a protective material on the top surface side thereof; and a reinforcing member (e.g. a frame member) is mounted on the periphery and bottom surface thereof.

Most of such frame members are made of a metal, and a whole photovoltaic module can be heavy and not convenient for transporting and moving. Although most frame members are made of light-weighted metal, e.g. aluminum or its alloys, they are still heavy. For the forgoing reasons, there is a need for improving the photovoltaic module to have a lighter frame.

### SUMMARY

It is therefore an objective of the present invention to provide a photovoltaic module with light-weighted frame.

In accordance with the foregoing and other objectives of the present invention, a photovoltaic module includes a photovoltaic panel and a frame securing to an edge of the photovoltaic panel. The frame includes a first metal portion and a first composite material of a first plastic material and first glass fibers. The first composite material is integrated with the first metal portion to form a unitary frame.

In accordance with the foregoing and other objectives of the present invention, a photovoltaic module includes a photovoltaic panel and a frame securing to an edge of the photovoltaic panel. The frame includes a first metal portion and a first composite material of a first silicone resin and first glass fibers. The first composite material is integrated with the first metal portion to form a unitary frame.

According to an embodiment disclosed herein, the first composite material is about 15 percent to about 25 percent of the frame in volume.

According to another embodiment disclosed herein, the first composite material is about 20 percent of the frame in volume.

According to another embodiment disclosed herein, the first composite material is fully enclosed by the first metal portion.

According to another embodiment disclosed herein, the first composite material is sandwiched between the first metal portion and the photovoltaic panel.

According to another embodiment disclosed herein, the first metal portion includes a first U-shaped cross-section, the first composite material includes a second U-shaped cross-section, the second U-shaped cross-section is fully enclosed by the first U-shaped cross-section.

According to another embodiment disclosed herein, the first metal portion includes a first U-shaped cross-section, the first composite material includes a second U-shaped cross-section, the second U-shaped cross-section is sandwiched between the first U-shaped cross-section and the photovoltaic panel.

According to another embodiment disclosed herein, the first metal portion includes an upper portion and a lower portion spaced from each other, the first composite material includes a U-shaped cross-section, an upper part of the U-shaped cross-section is sandwiched between the upper portion and the photovoltaic panel, and a lower part of the U-shaped cross-section is sandwiched between the lower portion and the photovoltaic panel.

According to another embodiment disclosed herein, the first metal portion includes aluminum or alloys thereof.

According to another embodiment disclosed herein, the photovoltaic module further includes a support beam disposed on a back surface of the photovoltaic panel, wherein the support beam includes a second metal portion and a second composite material of a second plastic material and second glass fibers. The second composite material is integrated with the second metal portion to form a unitary support beam.

According to another embodiment disclosed herein, the photovoltaic module further includes a support beam disposed on a back surface of the photovoltaic panel, wherein the support beam includes a second metal portion and a second composite material of a silicone resin and glass fibers. The second composite material is integrated with the second metal portion to form a unitary support beam.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates an exploded view of a photovoltaic module according to one preferred embodiment of this invention;

FIG. 2 illustrates a cross-sectional view of an edge portion of a photovoltaic module according to a first embodiment of this invention;

FIG. 3 illustrates a cross-sectional view of an edge portion of a photovoltaic module according to a second embodiment of this invention; and

FIG. 4 illustrates a cross-sectional view of an edge portion of a photovoltaic module according to a third embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

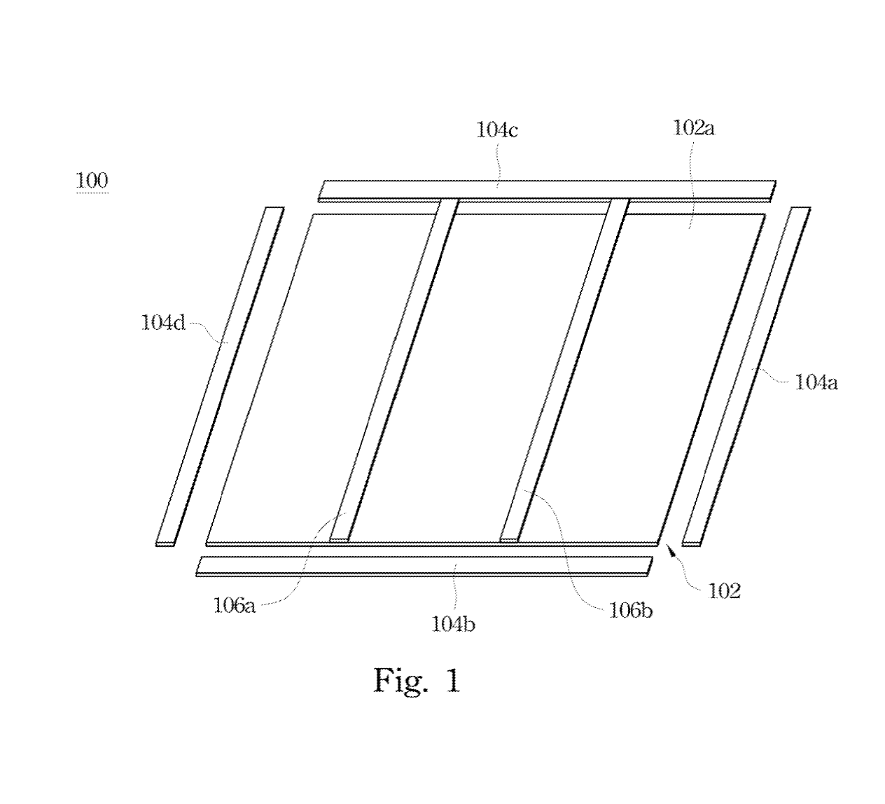

FIG. 1 illustrates an exploded view of a photovoltaic module 100 according to one preferred embodiment of this invention. The photovoltaic module 100 includes a photovoltaic panel 102 and four frames (104a, 104b, 104c, 104d) secured to all edges of the photovoltaic panel 102. Support beams (106a, 106b) can be optionally installed on a back surface 102a of the photovoltaic panel 102 to further enforce the strength of the photovoltaic module 100. In order to reduce the weight of the photovoltaic module 100, each frame (104a, 104b, 104c, 104d) can be made from a metal material (e.g. aluminum or alloys thereof) and a composite material including plastic materials plus glass fibers or silicone resins plus glass fibers. Metal portion is reduced in each frame to reduce the weight. The glass fibers are mixed with plastic materials or silicone resins to enforce the strength of the frame (104a, 104b, 104c, 104d) as a whole. Therefore, the photovoltaic module 100 can be lighter, but maintain its strength.

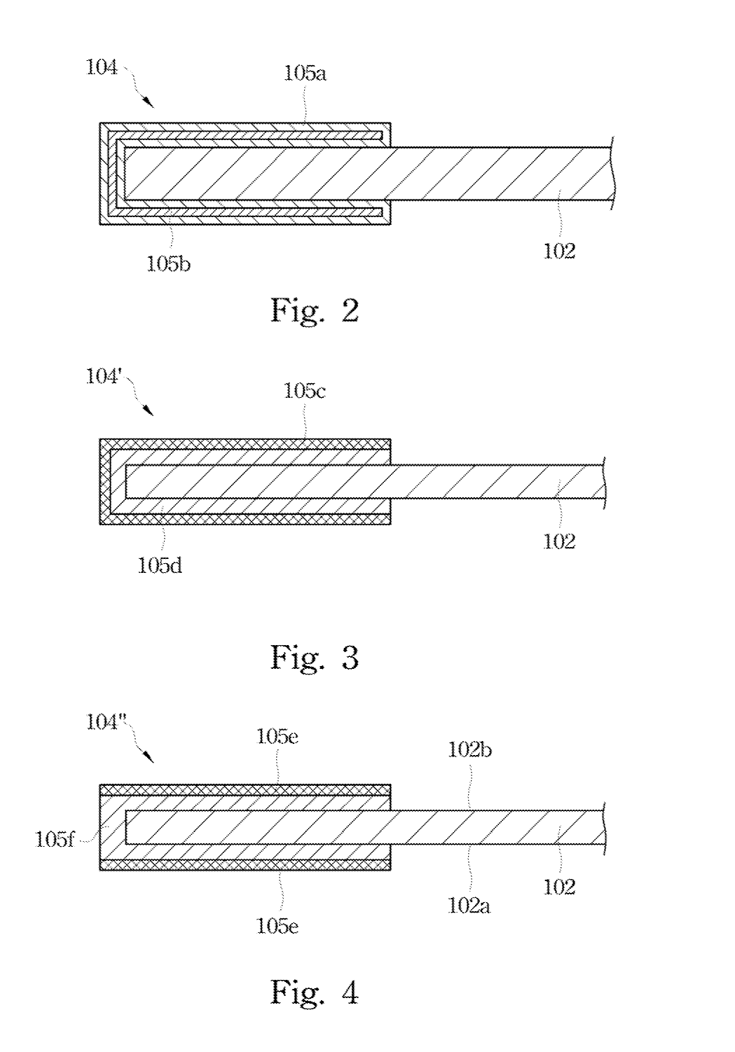

FIG. 2 illustrates a cross-sectional view of an edge portion of a photovoltaic module according to a first embodiment of this invention. The frame 104 includes a metal portion 105a (e.g. aluminum or alloys thereof) and a composite material 105b (e.g. plastic materials mixed with glass fibers or silicone resins mixed with glass fibers). The composite material 105b is fully enclosed or sealed by the metal portion 105a. This design can be achieved by injecting a liquid phase of the composite material 105b into a hollow metal portion 105a. From this view, the metal portion 105a has its U-shaped cross-section while the composite material 105b has its U-shaped cross-section. The U-shaped cross-section of the composite material 105b is fully enclosed by the U-shaped cross-section of metal portion 105a. Therefore, the metal portion 105a is in contact with the photovoltaic panel 102, but the composite material 105b is not. In this embodiment, the composite material 105b is about 15 percent to about 25 percent of the frame 104 in volume. Preferably, the composite material 105b is about 20 percent of the frame 104 in volume.

FIG. 3 illustrates a cross-sectional view of an edge portion of a photovoltaic module according to a second embodiment of this invention. The frame 104′ includes a metal portion 105c (e.g. aluminum or alloys thereof) and a composite material 105d (e.g. plastic materials mixed with glass fibers or silicone resins mixed with glass fibers). Basically, the composite material 105d is sandwiched between the metal portion 105c and the photovoltaic panel 102. This design can be achieved by injecting a liquid phase of the composite material 105d into a gap between the metal portion 105c and the photovoltaic panel 102 when the metal portion 105c and the photovoltaic panel 102 are assembled together. From this view, the metal portion 105c has a larger U-shaped cross-section while the composite material 105d has a smaller U-shaped cross-section. The U-shaped cross-section of the composite material 105d is sandwiched between the U-shaped cross-section of metal portion 105c and the photovoltaic panel 102. Therefore, the composite material 105d is in contact with the photovoltaic panel 102, but the metal portion 105c is not. In this embodiment, the composite material 105d is about 15 percent to about 25 percent of the frame 104′ in volume. Preferably, the composite material 105d is about 20 percent of the frame 104′ in volume.

FIG. 4 illustrates a cross-sectional view of an edge portion of a photovoltaic module according to a third embodiment of this invention. The frame 104″ includes a metal portion 105e (e.g. aluminum or alloys thereof) and a composite material 105f (e.g. plastic materials mixed with glass fibers or silicone resins mixed with glass fibers). This design can be achieved by injecting a liquid phase of the composite material 105f to enclose an edge of the photovoltaic panel 102, and then attach two pieces of the metal portion 105e thereon. From this view, the metal portion 105e has an upper portion and a lower portion spaced from each other while the composite material 105f has a U-shaped cross-section. An upper part of the U-shaped cross-section is sandwiched between the upper portion of the metal portion 105e and the photovoltaic panel 102 (e.g. a top surface 102b), and a lower part of the U-shaped cross-section is sandwiched between the lower portion of the metal portion 105e and the photovoltaic panel 102 (e.g. a back surface 102a). Therefore, the composite material 105f is in contact with the photovoltaic panel 102, but the metal portion 105e is not. In this embodiment, the composite material 105f is about 15 percent to about 25 percent of the frame 104″ in volume. Preferably, the composite material 105f is about 20 percent of the frame 104″ in volume.

Furthermore, the support beams (106a, 106b), as illustrated in FIG. 1, can be made from a metal portion (e.g. aluminum or alloys thereof) and a composite material (e.g. plastic materials mixed with glass fibers or silicone resins mixed with glass fibers) with similar designs.

According to the above-discussed embodiments, the photovoltaic module is equipped with an improved frame made from a metal portion (e.g. aluminum or alloys thereof) and a composite material (e.g. plastic materials mixed with glass fibers or silicone resins mixed with glass fibers), thereby reducing its weight but maintain its strength.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photovoltaic module comprising:
a photovoltaic panel; and
a frame securing to an edge of the photovoltaic panel, wherein the frame comprises:
a first metal portion; and
a first composite material comprising a first plastic material and first glass fibers, wherein the first composite material is integrated with the first metal portion to, form a unitary frame.

2. The photovoltaic module of claim 1, wherein the first composite material is about 15 percent to about 25 percent of the frame in volume.

3. The photovoltaic module of claim 1, wherein the first composite material is about 20 percent of the frame in volume.

4. The photovoltaic module of claim 1, wherein the first composite material is fully enclosed by the first metal portion.

5. The photovoltaic module of claim 1, wherein the first composite material is sandwiched between the first metal portion and the photovoltaic panel.

6. The photovoltaic module of claim 1, wherein the first metal portion comprises a first U-shaped cross-section, the first composite material comprises a second U-shaped cross-section, the second U-shaped cross-section is fully enclosed by the first U-shaped cross-section.

7. The photovoltaic module of claim 1, wherein the first metal portion comprises a first U-shaped cross-section, the first composite material comprises a second U-shaped cross-section, the second U-shaped cross-section is sandwiched between the first U-shaped cross-section and the photovoltaic panel.

8. The photovoltaic module of claim 1, wherein the first metal portion comprises an upper portion and a lower portion spaced from each other, the first composite material comprises a U-shaped cross-section, an upper part of the U-shaped cross-section is sandwiched between the upper portion and the photovoltaic panel, and a lower part of the U-shaped cross-section is sandwiched between the lower portion and the photovoltaic panel.

9. The photovoltaic module of claim 1, wherein the first metal portion comprises aluminum or alloys thereof.

10. The photovoltaic module of claim 1, further comprising a support beam disposed on a back surface of the photovoltaic panel, wherein the support beam comprises:
a second metal portion; and
a second composite material comprising a second plastic material and second glass fibers, wherein the second composite material is integrated with the second metal portion to form a unitary support beam.

11. A photovoltaic module comprising:
a photovoltaic panel; and
a frame securing to an edge of the photovoltaic panel, wherein the frame comprises:
a first metal portion; and
a first composite material comprising a first silicone resin and first glass fibers, wherein the first composite material is integrated with the first metal portion to form a unitary frame.

12. The photovoltaic module of claim 11, wherein the first composite material is about 15 percent to about 25 percent of the frame in volume.

13. The photovoltaic module of claim 11, wherein the first composite material is about 20 percent of the frame in volume.

14. The photovoltaic module of claim 11, wherein the first composite material is fully enclosed by the first metal portion.

15. The photovoltaic module of claim 11, wherein the first composite material is sandwiched between the first metal portion and the photovoltaic panel.

16. The photovoltaic module of claim 11, wherein the first metal portion comprises a first U-shaped cross-section, the first composite material comprises a second U-shaped cross-section, the second U-shaped cross-section is fully enclosed by the first U-shaped cross-section.

17. The photovoltaic module of claim 11, wherein the first metal portion comprises a first U-shaped cross-section, the first composite material comprises a second U-shaped cross-section, the second U-shaped cross-section is sandwiched between the first U-shaped cross-section and the photovoltaic panel.

18. The photovoltaic module of claim 11, wherein the first metal portion comprises an upper portion and a lower portion spaced from each other, the first composite material comprises a U-shaped cross-section, an upper part of the U-shaped cross-section is sandwiched between the upper portion and the photovoltaic panel, and a lower part of the U-shaped cross-section is sandwiched between the lower portion and the photovoltaic panel.

19. The photovoltaic module of claim 11, wherein the first metal portion comprises aluminum or alloys thereof.

20. The photovoltaic module of claim 11, further comprising a support beam disposed on a back surface of the photovoltaic panel, wherein the support beam comprises:
a second metal portion; and
a second composite material comprising a second silicone resin and second glass fibers, wherein the second composite material is integrated with the second metal portion to form a unitary support beam.
